(19) United States
(12) Patent Application Publication
(10) Pub. No.: US 2023/0221898 A1
(43) Pub. Date: Jul. 13, 2023

(54) SHIELD ENCLOSURES FOR MEMORY MODULES

(71) Applicant: HEWLETT-PACKARD DEVELOPMENT COMPANY, L.P., Spring, TX (US)

(72) Inventors: Ying-Chi Chou, Taipei City (TW); Chien Fa Huang, Taipei City (TW); Yi-Feng Lin, Taipei City (TW)

(21) Appl. No.: 17/574,928

(22) Filed: Jan. 13, 2022

(51) Int. Cl. G06F 3/06

(52) U.S. Cl. CPC G06F 3/0614; G06F 3/0653; G06F 3/0673

(57) ABSTRACT

In example implementations, an apparatus is provided. The apparatus includes a polymer based enclosure, an absorber, and a connection interface. The polymer based enclosure is shaped to enclose a memory module connected to a memory module connection interface on a printed circuit board. The absorber is coated over the polymer based enclosure to block radio frequency signals generated by the memory modules. The connection interface is to connect to the memory module connection interface.

### BACKGROUND

Computing devices can be used to execute various applications and programs. A processor is deployed in a computing device to execute the applications and programs. The computing device can have additional components and modules (e.g., memory modules, wireless radios, graphical processors, and the like) that help with the execution of various tasks and/or applications.

The modules can emit radio frequency (RF) signals during operation. As the power of certain modules improves, the modules can emit more RF noise.

### BRIEF DESCRIPTION OF THE DRAWINGS

FIG. 1 is a block diagram of an example computing device of the present disclosure;

FIG. 2 is block diagram of an example unassembled shielding enclosure of the present disclosure;

FIG. 3 illustrates an example exploded view of the shielding enclosure of the present disclosure before being installed over memory modules;

FIG. 4 illustrated an example view of the shielding enclosure of the present disclosure before being installed over memory modules;

FIG. 5 illustrates a close up view of an example connection interface of the shielding enclosure connected to a slot latch of the memory module connection interface;

FIG. 6 illustrates a cross-sectional close up view of an example connection interface of the shielding enclosure connected to a slot latch of the memory module connection interface;

FIG. 7 illustrates an example of the shielding enclosure with a plurality of dividers; and

FIG. 8 illustrates another example of the shielding enclosure with a plurality of dividers.

### DETAILED DESCRIPTION

Examples described herein provide a shield enclosure for memory modules. As discussed above, computing devices can be used to execute various applications and programs. A computing device can have additional components and modules, such as memory modules or wireless communication radios. However, as these components and modules improve, the components can consume more power or generate higher frequency signals/noise. The proximity of these components and the improved power and signal strength, which correlates to greater RF noise, can cause operation of one component to interfere with operation of other components within the computing device.

For example, as memory modules (e.g., random access memory) improve over time, the memory modules can emit higher radio frequency noise that can interfere with operation of other modules, such as the WiFi radio.

Previous solutions have attempted to create individual metal enclosures around each module. However, attempting to attach individual enclosures around each memory module can be cumbersome. The individual enclosures can also create unwanted side effects (e.g., the RF noise can be amplified through the metal piece enclosure as an antenna). In addition, metal can be difficult to shape and may not perform well as a shielding enclosure.

The present disclosure provides a shield enclosure that can enclose multiple memory modules with a single enclosure. The shield enclosure of the present disclosure uses a polymer frame that can be easily molded into a desired shape that is covered with an absorber. The polymer frame can also prevent the antenna side effect described above.

Additional absorbers can be included as dividers inside of the enclosure. The dividers provide additional surface area that can act to block the RF signals generated by the memory modules. The shield enclosure of the present disclosure can be connected to the existing memory module connections without modification to the mother board or printed circuit board.

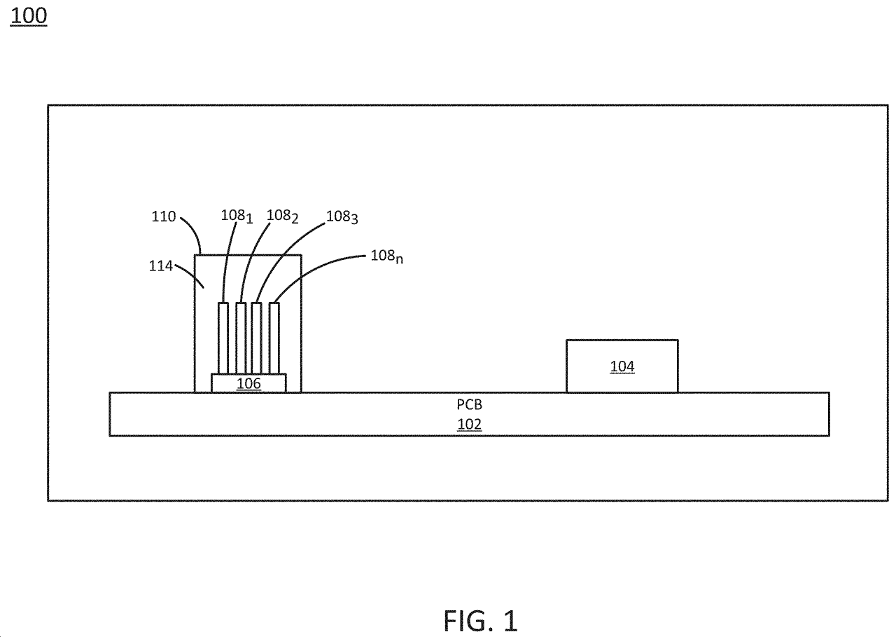

FIG. 1 illustrates an example computing device 100 of the present disclosure. In an example, the computing device 100 may be a desktop computer, a laptop computer, a tablet computer, or the like.

It should be noted that the computing device 100 has been simplified for ease of explanation. Although various example components are illustrated in FIG. 1, it should be noted that the computing device 100 may include additional components that are not shown. For example, the computing device 100 may include a processor, input/output devices (e.g., a display, a monitor, a keyboard, a mouse, a trackpad, and the like), a power supply, various interfaces (e.g., a universal serial bus (USB) interface), communications interfaces (e.g., a wired or wireless communication interface such as WiFi, Ethernet, and the like), and so forth.

In an example, the computing device 100 may include a printed circuit board (PCB) 102, a wireless communication radio 104, and memory modules 108₁ to 108ₙ (hereinafter referred to individually as a memory module 108 or collectively as memory modules 108) connected to a memory module connection interface 106.

In an example, the wireless communication radio 104 may be a Wi-Fi radio. For example, the wireless communication radio 104 may be a Wi-Fi6 or Wi-Fi6e radio that can transmit and receive RF signals.

In an example, the memory modules 108 may be random access memory (RAM) modules. The memory modules 108 may be inserted into a respective memory module slot of the memory module connection interface 106. In an example, the memory modules 108 may be a double data rate 5 (DDR5) RAM.

As noted above, during operation, the memory modules 108 may generate RF noise. The RF noise may interfere with the operation of the wireless communication radio 104. For example, the RF noise generated by the memory modules 108 may cause the RF communication signals transmitted or received by the wireless communication radio 104 experience loss or delay.

Previous solutions may have tried to individually shield each memory module 108. However installing a shield around each memory module 108 individually may be cumbersome and inefficient. In addition, the shield may cause modifications to be made to the PCB 102 to install the individual shields around each memory module 108.

The present disclosure provides a single shielding enclosure 110. The shielding enclosure 110 may include an interior volume 114 that may enclose the memory modules 108 as a group. In other words, the shielding enclosure 110 may have dimensions that allow the shielding enclosure 110 to enclose all of the memory modules 108 or whatever maximum number of memory modules 108 that can be accommodated by the memory module connection interface 106.

In addition, the shielding enclosure 110 may be installed using the existing memory module connection interface 106. In other words, no modifications to the PCB 102 need to be made to install the shielding enclosure 110. For example, the shielding enclosure 110 may include a connection interface that can connect to slot latches of the memory module connection interface 106, as discussed in further details below and shown in FIGS. 3-6.

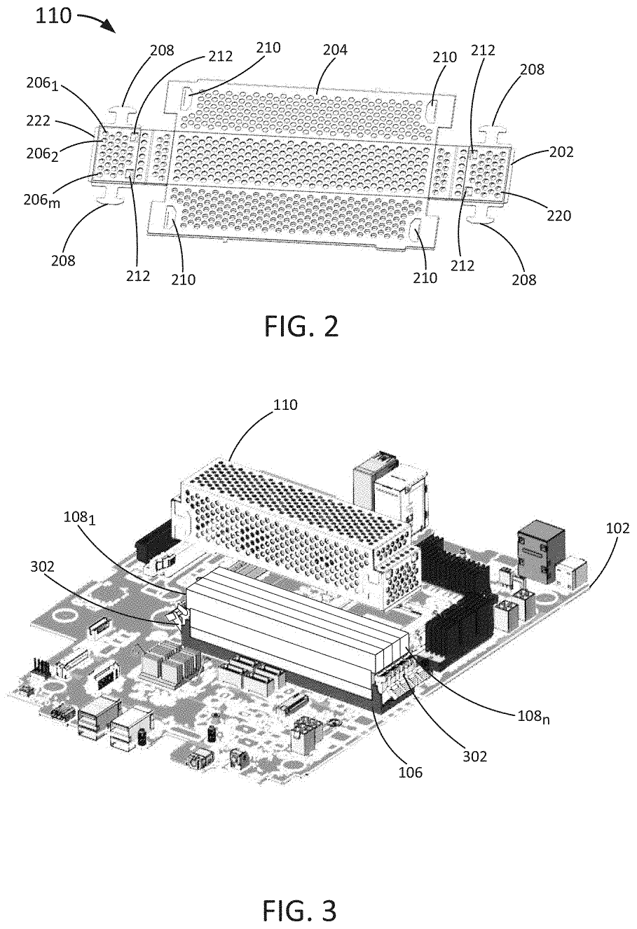

FIG. 2 illustrates an example of the shielding enclosure 110. The shielding enclosure 110 illustrated in FIG. 2 is unassembled. In an example, the shielding enclosure 110 may include a polymer based enclosure 202. The polymer based enclosure 202 may provide a frame for an absorber 204. For example, the polymer based enclosure 202 may provide a rigid frame, base, or structure that can support the absorber 204. In an example, the polymer based enclosure 202 may be fabricated from a polymer, such as Mylar (e.g., polyethylene terephthalate).

In an example, the absorber 204 may be applied to coat an interior surface (e.g., a side that faces the interior volume 114) of the polymer based enclosure 202. The absorber 204 may be any type of material that can absorb RF signals or electromagnetic signals.

The absorber 204 may be a magnet absorber or a foam absorber. A magnetic absorber may be a polymeric material that is filled with magnetic particles. The magnetic absorber may provide high permeability and high permittivity, which are both effective in eliminating high-frequency electromagnetic interference. The magnetic absorber may be applied in layers that are 0.1 millimeters (mm) to 3 mm.

A foam absorber may be based on open-celled foam impregnated with a carbon coating. The foam absorber may provide a product that is lossy at microwave frequencies and acts as a free space resistor to incoming electromagnetic energy. The foam absorber may be applied in layers that are 3.2 mm to 6.4 mm.

In an example, the absorber 204 may be applied with an adhesive. The absorber 204 may cover most of the surface area (e.g., 95% or greater) of the interior surface of the polymer based enclosure 202.

In an example, the polymer based enclosure 202 may include tabs 208 that can be inserted into corresponding openings 210. The tabs 208 may have a shape that can be inserted into the openings 210 to lock the tabs 208 into position when the polymer based enclosure 202 is assembled or folded into its final shape.

In an example, the polymer based enclosure 202 may include a connection interface, as discussed above. The connection interface may include tabs 212. The tabs 212 may have a line or a pre-cut crease that allows the tabs 212 to be slightly folded or bent. The tabs 212 may interact with the slot latch of the memory module connection interface 106, as discussed in further details below.

The tabs 212 may have a generally rectangular shape. However, it should be noted that the tabs 212 may have any shape including, for example, a square, a semicircle, a polygon, and the like.

In an example, the polymer based enclosure 202 may include two tabs 212 on each end 220 and 222 of the polymer based enclosure. The tabs 212 may be on opposing sides of each end 220 and 222.

In an example, the shielding enclosure 110 may include a plurality of openings 206₁ to 206ₘ (hereinafter referred to individually as an opening 206 or collectively as openings 206). The openings 206 may be formed in the polymer based enclosure 202 and the absorber 204, such that the openings are aligned when the absorber 204 is applied to the polymer based enclosure 202.

The openings 206 may provide a vent. The vent may help dissipate heat away from the memory modules 108 to prevent overheating or operational failure of the memory modules 108. However, the openings 206 may cause the shielding enclosure 110 to have a poorer performance of RF noise blocking.

As a result, the openings 206 may be optional. In other words, some examples of the shielding enclosure 110 may include no openings 206 or no vent. When the shielding enclosure 110 has no openings 206, other cooling mechanisms may be deployed to cool the memory modules 108. For example, cooling tubes/coils, heat sinks, mechanical fans, and the like may be deployed to control heat dissipations in the interior volume 114 of the shielding enclosure 110. In another example, the number of openings 206 may be tuned to provide acceptable RF noise blocking performance and acceptable venting to dissipate heat away from the memory modules 108.

FIG. 3 illustrates an exploded view of the shielding enclosure 110 before being installed on the memory module connection interface 106. When assembled, the shielding enclosure 110 may have a generally rectangular shape. The dimensions of the shielding enclosure 110 may be set to be similar to the memory module connection interface 106 and the memory modules 108. For example, the dimensions of the shielding enclosure 110 may be large enough to enclose the memory modules 108 and connect to the memory module connection interface 106. Said another way, the shielding enclosure 110 may have a length and width approximately equal to the length and width of the memory module connection interface 106 and have a height that is approximately equal to a height of the memory modules 108 when inserted into the memory module connection interface 106.

FIG. 3 also illustrates slot latches 302 of the memory module connection interface 106. For example, the memory module connection interface 106 may include a plurality of memory module slots. Each slot may include a pair of slot latches on opposite ends to secure a memory module 108 inserted into a respective slot.

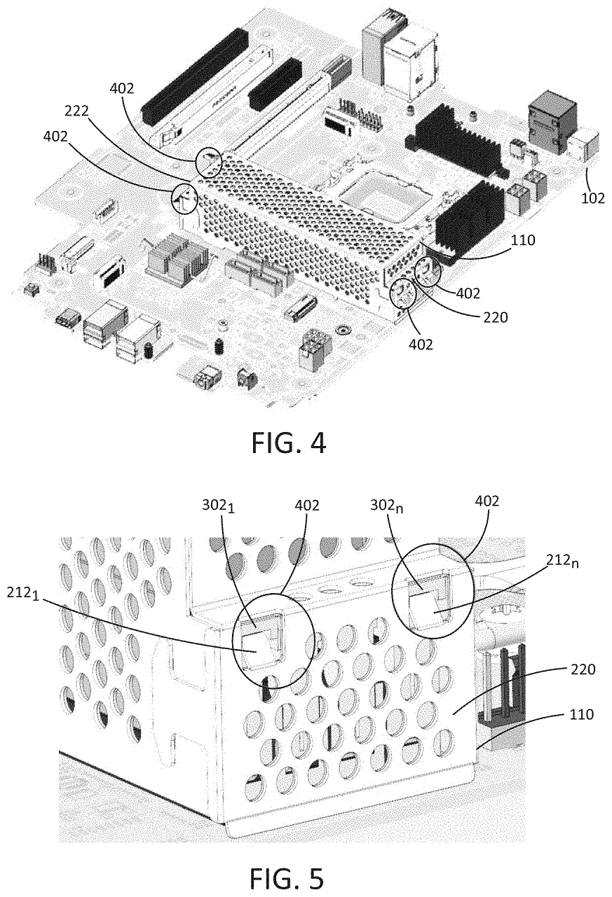

FIG. 4 illustrates an example of the shielding enclosure 110 that is installed onto the memory module connection interface 106. The connection interface of the shielding enclosure 110 may be connected to the memory module connection interface 106. For example, the tabs 212 may be inserted into the slot latches 302. The tabs 212 may be inserted into the slot latches 302 as shown by the areas highlighted by circles 402 on the first end 220 and the second end 222 of the shielding enclosure 110.

FIG. 5 illustrates a close-up view of the area highlighted by the circles 402 of FIG. 4. As noted above, the tabs 212 may include a folding line or crease that can be pushed in towards the slot latch 302. In an example, the tabs 212 may be located on opposite ends of the first end 220 and the second end 222 of the shielding enclosure 110, as noted above. Said another way, the first end 220 may include a first tab 212₁ that is positioned to be aligned with a first slot latch 302₁. The first end 220 may include a second tab 212₂ on an edge of the first end 220 opposite the first tab 212₁ that is aligned with a last slot latch 302ₙ. Thus, the first tab 212₁ and the second tab 212₂ may be aligned with the first slot latch 302₁ and the last slot latch 302ₙ. The tabs 212 on the second end 222 (not shown) may be similarly aligned with the first and last slot latches 302 on the opposite end of the memory module connection interface 106.

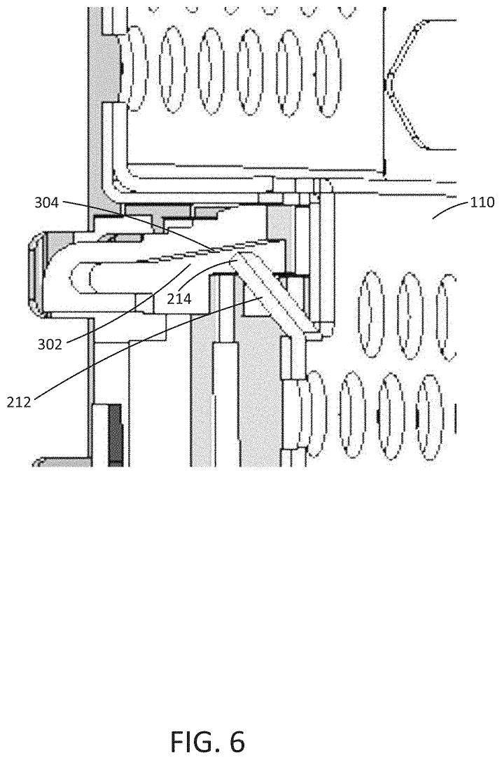

FIG. 6 illustrates a cross-sectional close up view of the connection interface connected to the slot latch 302. As discussed above, the tab 212 can be pushed towards the slot latch 302. The tab 212 may have an end 214. The tab 212 may be pressed towards the slot latch 302 with enough force to push the end 214 past a point where the end 214 contacts a surface 304 of the slot latch 302. Thus, the shielding enclosure 110 may be secured to the memory module connection interface 106 when the tab 212 is in the position as shown in FIG. 6.

To remove the shielding enclosure 110, the tab 212 may be pulled away from the slot latch 302. The tab 212 may be pulled with enough force to pull the end 214 past a point where the end 214 contacts the surface 304. Thus, the shielding enclosure 110 may be installed onto the slot latches 302 of the existing memory module connection interface 106 without modifications to the PCB 102 to accommodate a new connection mechanism.

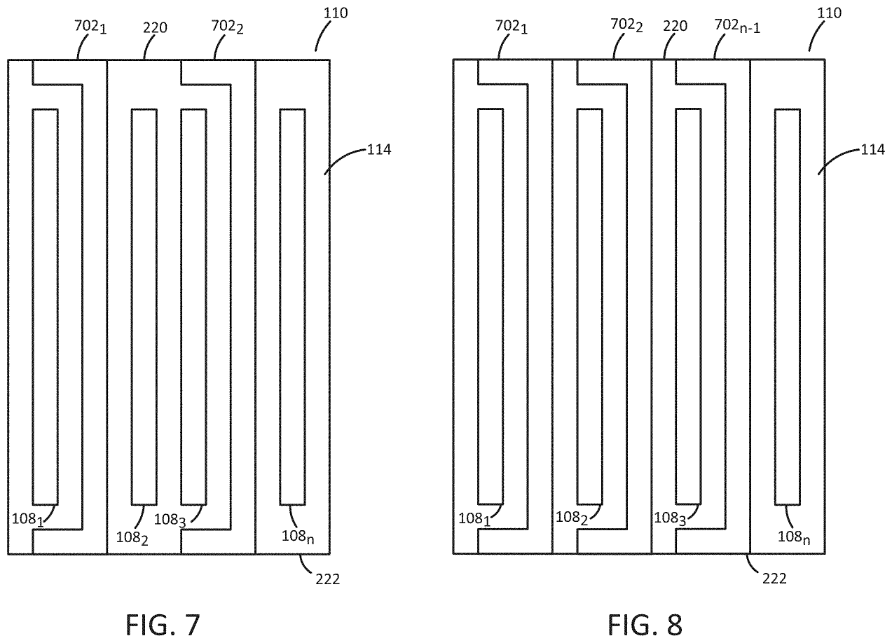

FIG. 7 illustrates an example of the shielding enclosure 110 with dividers 702₁ and 702₂. The shielding enclosure 110 may also have no openings 206. In other words, the shielding enclosure 110 illustrated in FIG. 7 may have no venting or vent openings.

In an example, the dividers 702₁ and 702₂ may be installed on an interior side of the interior volume 114 of the shielding enclosure 110. The dividers 702₁ and 702₂ may have a length that spans from a first end 220 to the second end 222 of the shielding enclosure 110.

In an example, the dividers 702₁ and 702₂ may have a Mylar body covered by the absorber 204. For example, the dividers 702₁ and 702₂ may be entirely coated by the absorber 204. The dividers 702₁ and 702₂ may increase the surface area of the absorber 204 inside of the shielding enclosure 110. Thus, the dividers 702₁ and 702₂ may help to increase the amount of RF noise blocking provided by the shielding enclosure 110.

FIG. 8 illustrates another example of the shielding enclosure 110 with a plurality of dividers 702₁ to 702ₙ₋₁ (hereinafter also referred to individually as a divider 702 or collectively as dividers 702). The shielding enclosure 110 illustrated in FIG. 8 may also have no openings 206. In other words, the shielding enclosure 110 may have no venting or vent openings.

In an example, the dividers 702₁ to 702ₙ₋₁ may be installed on an interior side of the interior volume 114 of the shielding enclosure 110. The dividers 702₁ to 702ₙ₋₁ may have a length that spans from a first end 220 to the second end 222 of the shielding enclosure 110.

In an example, the dividers 702₁ to 702ₙ₋₁ may have a Mylar body covered by the absorber 204. For example, the dividers 702₁ to 702ₙ₋₁ may be entirely coated by the absorber 204. The dividers 702₁ to 702ₙ₋₁ may increase the surface area of the absorber 204 inside of the shielding enclosure 110. Thus, the dividers 702 may help to increase the amount of RF noise blocking provided by the shielding enclosure 110.

In an example, the number of dividers 702₁ to 702ₙ₋₁ may be one fewer than a total number of memory modules 108₁ to 108ₙ. In other words, the shielding enclosure 110 illustrated in FIG. 8 may include a divider 702 between each pair of memory modules 108. Said another way, each pair of adjacent memory modules 108 may have a divider 702 located between the adjacent memory modules 108.

The performances of various configurations of shielding enclosures were tested. The configurations included: (1) a vented shielding enclosure without dividers, (2) a vented shielding enclosure with dividers, (3) a shielding enclosure with two dividers without vents (e.g., the example shielding enclosure 110 illustrated in FIGS. 7), and (4) a vented shielding enclosure with three dividers. The different configurations of the shielding enclosures were tested against an 802.11 WiFi6e radio that operated at channel frequencies between 5925 megahertz (MHz) to 6245 MHz at 20 MHz intervals. A RF noise blocking threshold was set to noise levels of less than −90 decibels per milliwatt (dBm) (e.g., noise levels less than −90 dBm or more negative values were desired).

The testing showed that the shielding enclosure without vents (configuration 3) performed better than the shielding enclosures with vents. In addition, the testing showed that the number of dividers also affected RF noise blocking performance (e.g., the shielding enclosure with three dividers (configuration 4) performed worse than the shielding enclosure with two dividers (configuration 2)).

Overall, the various configurations (1)-(4) limited RF noise to less than −90 dBm across many of the channel frequencies between 5925 MHz to 6245 MHz. However, it was found that the configuration of the shielding enclosure without vents and with two dividers (configuration 3) (e.g., the example shown in FIG. 7) performed the best across most of the channel frequencies between 5925 MHz to 6245. For example, the configuration (3) limited RF noise to noise levels less than −90 dBm for a plurality of different channel frequencies between 5925 MHz to 6245. More specifically, the configuration (3) was able to decrease the RF noise by approximately 7% around a frequency range around 6000 MHz compared to other enclosures. The frequency range around 6000 (e.g., between 5945 MHz to 6225 MHz) can be a problematic frequency range for CPU/memory/WiFi radio harmonics.

Thus, various parameters may be tuned to achieve a desired level of RF noise blocking, while maintain sufficient venting. For example, the shielding enclosure may have partial venting (e.g., openings 206 on one side of the polymer based enclosure 202) with fewer dividers 702 to balance heat dissipation against RF noise blocking. Thus, the shielding enclosure 110 with three dividers 702 with no venting illustrated in FIG. 8 may provide slightly poorer performance than the shielding enclosure 110 illustrated in FIG. 7.

Thus, the present disclosure provides a shielding enclosure that can enclose all of the memory modules of a computing device with a single enclosure. The shielding enclosure can provide sufficient RF noise blocking performance. In addition, the shielding enclosure of the present disclosure can include a connection interface that can connect to an existing memory module connection interface without modifying the PCB.

It will be appreciated that variants of the above-disclosed and other features and functions, or alternatives thereof, may be combined into many other different systems or applications. Various presently unforeseen or unanticipated alternatives, modifications, variations, or improvements therein may be subsequently made by those skilled in the art which are also intended to be encompassed by the following claims.

1. An apparatus, comprising:
a polymer based enclosure that is shaped to enclose a memory module connected to a memory module connection interface on a printed circuit board;
an absorber coated over the polymer based enclosure to block radio frequency signals generated by the memory module; and
a connection interface to connect to the memory module connection interface.

2. The apparatus of claim 1, wherein the polymer comprises Mylar.

3. The apparatus of claim 1, wherein the absorber comprises a magnetic absorber.

4. The apparatus of claim 1, wherein the absorber comprises a foam absorber.

5. The apparatus of claim 1, wherein the absorber covers an entire interior surface of the polymer based enclosure.

6. The apparatus of claim 1, wherein the apparatus limits noise to noise levels less than −90 decibel milliwatts (dBm) for a plurality of different channel frequencies between 5925 millihertz (MHz) to 6245 MHz.

7. The apparatus of claim 1, wherein the connection interface comprises a tab to push towards a slot latch of the memory module connection interface.

8. An apparatus, comprising:
a polymer based enclosure that is shaped to enclose memory modules connected to a memory module connection interface on a printed circuit board;
an absorber coated over the polymer based enclosure to block radio frequency signals generated by the memory modules; and
a divider coupled to an inner volume of the polymer based enclosure.

9. The apparatus of claim 8, wherein the polymer comprises Mylar.

10. The apparatus of claim 8, wherein the divider comprises an absorber.

11. The apparatus of claim 8, wherein the divider comprises a plurality of dividers.

12. The apparatus of claim 11, wherein the plurality of dividers comprises a divider positioned between each pair of the memory modules connected to the printed circuit board.

13. The apparatus of claim 8, wherein the apparatus decreases RF noise by approximately 7% around a frequency range of 6000 MHz.

14. A computing device, comprising:
a plurality of memory modules;
a memory module connection interface connected to a printed circuit board (PCB), wherein the memory module connection interface comprises a plurality of memory module slots to receive a respective memory module of the plurality of memory modules;
a wireless communication radio coupled to the PCB; and
a shielding enclosure coupled to the memory module connection interface to enclose the plurality of memory modules and to shield the wireless communication radio from radio frequency noise emitted from the plurality of memory modules.

15. The computing device of claim 14, wherein the shielding enclosure comprises:
a Mylar frame, wherein an interior surface of the Mylar frame is coated with an absorber.

16. The computing device of claim 15, wherein the shielding enclosure further comprises:
a plurality of dividers located within an interior volume of the Mylar frame.

17. The computing device of claim 16, wherein each divider of the plurality of dividers is coated with the absorber.

18. The computing device of claim 16, wherein a number of the plurality of dividers is equal to one fewer than a number of the plurality of memory modules.

19. The computing device of claim 14, wherein at least one memory module of the plurality of memory modules comprises a double data rate 5th generation (DDRS) memory module.

20. The computing device of claim 14, wherein the wireless communication radio comprises a Wi-Fi6 radio or a Wi-Fi6e radio.
